(19) United States
(12) Patent Application Publication
(10) Pub. No.: US 2019/0057319 A1
(43) Pub. Date: Feb. 21, 2019

(54) Hyper Quantum Bits

(71) Applicant: Corey Reaux-Savonte, London (GB)

(72) Inventor: Corey Reaux-Savonte, London (GB)

(21) Appl. No.: 16/103,031

(22) Filed: Aug. 14, 2018

(30) Foreign Application Priority Data
Aug. 16, 2017 (GB) GB1713132.7

(51) Int. Cl. G06N 99/00; H01S 3/00; G01R 19/00

(52) U.S. Cl. CPC G06N 99/002; G01R 19/0092; H01S 3/0014

(57) ABSTRACT

Design and method for achieving computational bits with three states or more.

### FIELD OF THE INVENTION

The disclosed embodiments relate to physics and computer engineering.

### BACKGROUND

Quantum bits have always been difficult to make viable for use in everyday systems, and have been limited to three states—0, 1, or “both”. This is no longer the case.

### SUMMARY

The disclosed invention is a bit system which achieves three or more states for a single bit.

In an aspect of the invention, a measuring system, operating as a bit, attains a single bit value based on the quantity of that which it is measuring.

### DESCRIPTION OF DRAWINGS

FIG. 1

An example of a hyperbit configuration using two lasers and a pressure detector.
101—Switch 1
102—Switch 2
103—Laser 1
104—Laser 2
105—Laser Beam 1
106—Laser Beam 2
107—Vacuum Tubing
108—Pressure Detector

FIG. 2

An example of a hyperbit configuration where laser beams are merged into one.
201—A collimating lens.

### DETAILED DESCRIPTION OF EMBODIMENTS

Reference will now be made in detail to embodiments. In the following detailed description, numerous specific details are set forth in order to provide a thorough understanding of the present invention. However, it will be apparent to one of ordinary skill in the art that the present invention may be practiced without these specific details. In other instances, well-known methods, procedures, components and networks have not been described in detail so as not to unnecessarily obscure aspects of the embodiments.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

The term “hyperbit” is a shortened version of “hyper quantum bit”.

The various applications and uses of the invention that may be executed may use at least one common component capable of allowing a user to perform at least one task made possible by said applications and uses. One or more functions of the component may be adjusted and/or varied from one task to the next and/or during a respective task. In this way, a common architecture may support some or all of the variety of tasks.

Unless clearly stated, the following description is not to be read as:
the assembly, position or arrangement of components;
how components are to interact; or
the order in which steps must be taken to compose the present invention.

Attention is now directed towards embodiments of the invention.

There are four requirements for the creation of a hyperbit:
1. At least one type of object that can stream continuously;
2. Two or more separate object streams;
3. Switches to turn streams on and off; and
4. A measuring device operating as a bit.

The two or more streaming objects need to be directed at the measuring device. The measuring device needs to be calibrated to measure the value of a specific property of the streams. Then, its bit value is determined based on the measured value of those properties. As a switch turns a stream on and off, the bit value of the measuring device changes.

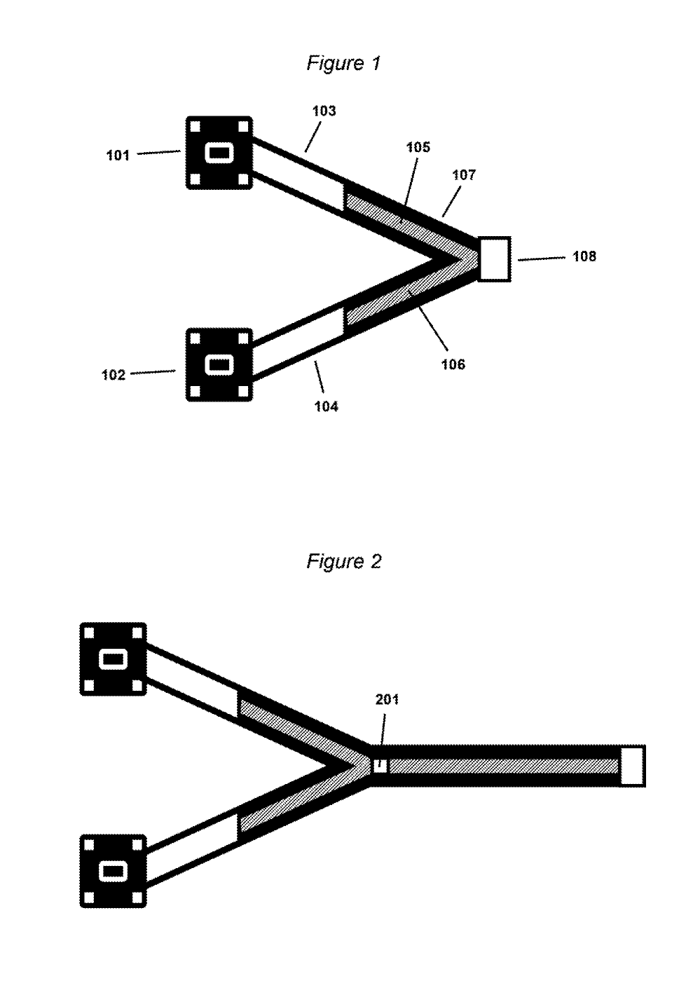

An example will be given based on light and pressure using FIG. 1.

FIG. 1 features two lasers, each with their own switch, attached to vacuum tubes through which their beam can travel, connected to a pressure detector. The vacuum tubes allow the photons of the laser beam to constantly travel at the speed of light, meaning they always exert (approximately) the same amount of pressure on the detector, making the detector much easier to calibrate. This two-stream setup can be used to achieve either three or four bit states, depending on the strength of each laser.

If the lasers are the same strength, three states can be achieved:
0—No laser on.
1—Either laser on.
2—Both lasers on.

This is because, with both lasers being the same strength, they exert the same amount of pressure on the detector, and the detector's calibration will produce the same result. However, with lasers of different strengths, four states can be achieved:
0—No laser on.
1—Weaker laser on.
3—Stronger laser on.
3—Both lasers on.

Imagining the strength of the weaker laser was 1, and the strength of the stronger laser was 3, mathematically this will equate to, in terms of pressure value:
0—No lasers, no pressure.
1—Weaker laser only.
3—Stronger laser only.
4—Both lasers combined.

With the detector calibrated to look for those pressure exertion values, its bit value can be determined based on the pressure being exerted upon it at any given time.

FIG. 2 is similar to FIG. 1, but features a collimating lens which merges the two individual beams into one. Given the ability for photons to superposition, pressure can still be combined when overlapping.

To achieve more than four states, more lasers need to be added.
Using three individual beams, you′d be able to achieve a maximum of eight states of pressure—0, A, B, C, AB, AC, BC, and ABC.
Four individual beams? Up to sixteen states—0, A, B, C, D, AB, AC, AD, BC, BD, CD, ABC, ABD, ACD, BCD, ABCD.

It's important to make sure multiple lasers don't equal the same value as a single laser in order to achieve the maximum possible number of bit states. For example, if the laser pressures were 1, 2, and 3, 1 and 2 being on would create the same pressure as just 3, which is bad for computation as the detector wouldn't know if both 1 and 2 were on or just 3. Using the standard doubling convention would ensure no two lasers create the same total pressure, while collectively being able to create every possible value up to the total value of all lasers combined. So, for instance, four lasers with pressure values of 1, 2, 4 and 8 would produce:

| Laser Values | Pressure Value |
|---|---|
| None | 0 |
| 1 | 1 |
| 2 | 2 |
| 1 and 2 | 3 |
| 4 | 4 |
| 1 and 4 | 5 |
| 2 and 4 | 6 |
| 1 and 2 and 4 | 7 |
| 8 | 8 |
| 1 and 8 | 9 |
| 2 and 8 | 10 |
| 1 and 2 and 8 | 11 |
| 4 and 8 | 12 |
| 1 and 4 and 8 | 13 |
| 2 and 4 and 8 | 14 |
| 1 and 2 and 4 and 8 | 15 |

With a detector calibrated to detect the sixteen states, every state can be recognised. This can be applied to any number of lasers by determining their maximum possible number of states, how many states will be used, and calibrating the detector correctly.

The switches can be any device with at least two states, such as a transistor, that can be used to control the stream of an object. Depending on the types of switches used, hyperbits may hold their state even when not in use:
Persistent—If the type of switch used remains in the last used state even when not in use, the hyperbit holds its value and resumes the last used state when put in use.
Non-Persistent—These switches reset to a zero value every time they are no longer in use.

Hyperbits work best using photons and pressure detectors because photons are unaffected by gravity, meaning they will always travel at a single speed in a vacuum and create the same pressure, which is ideal for use both in space and within the gravitational reach of a body. However, they can be created using other streamable objects. For example, by connecting multiple wires to an instrument such as an ammeter and using only the reading from the ammeter, the same results can be achieved as long as the flow through each wire can be turned on and off, and the current passing through is controlled. If the precise current flowing can't be guaranteed, the measuring device needs to be calibrated to work within a range. The downside to many of these other methods is the increased propensity for failure, which, even by the tiniest amount, could easily lead to data corruption, failed execution of instructions, the wrong execution of instructions etc, as well as the constant need to recalibrate the measuring device.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

1. A bit system, comprising
at least one type of object that can stream continuously;
two or more separate object streams;
switches to turn streams on and off; and
a measuring device operating as a bit;
wherein:
the switches are used to turn each object stream on and off;
the object streams are directed towards a measuring device; and
the measuring device attains a bit value based on the current measurement.

2. A method of attaining three or more bit values for a single bit, wherein the method comprises:
using switches to control two or more streaming objects;
using a measuring device, operating as a bit, to measure the quantity of a property created by two or more streaming objects; and
calibrating the measuring device to represent a bit value based on the current measurement of the property.
